(19) United States
(12) Patent Application Publication
(10) Pub. No.: US 2025/0226322 A1
(43) Pub. Date: Jul. 10, 2025

(54) INTERCONNECT LAYER WITH DIFFERENT DIELECTRIC REGIONS

(71) Applicant: Taiwan Semiconductor Manufacturing Co., Ltd., Hsinchu (TW)

(72) Inventors: Chung-Ren Sun, Kaohsiung City (TW); Kun-Ei Chen, Tainan County (TW); Chun-Jen Chen, New Taipei City (TW); Sheng-Tang Wang, Hsinchu City (TW); Shih-Chi Lin, HsinChu City (TW); Kai-Shiung Hsu, Hsinchu City (TW); Kang-Min Kuo, Hsinchu County (TW); Su-Yu Yeh, Tainan City (TW)

(73) Assignee: Taiwan Semiconductor Manufacturing Co., Ltd., Hsinchu (TW)

(21) Appl. No.: 18/405,973

(22) Filed: Jan. 5, 2024

(51) Int. Cl. H01L 23/532; H01L 21/768; H01L 23/528

(52) U.S. Cl. CPC H01L 23/5329; H01L 21/76802; H01L 23/528; H01L 23/53295

(57) ABSTRACT

The present disclosure is directed to a structure of an interconnect layer and a method of forming the structure. The interconnect layer includes first and second regions. The first region includes a first dielectric layer and a first interconnect structure. The second region includes a second dielectric layer and a second interconnect structure. The first region has a first ratio of a metal surface area to a non-metal surface area in the first region. The second region has a second ratio of a metal surface area to a non-metal surface area in the second region. The first and second ratios are different. The first and second dielectric layers include dielectric materials selected and/or treated differently according to the first and second ratios to substantially match polishing rates of the first and second regions in a planarization process.

### BACKGROUND

In semiconductor manufacturing, some fabrication processes, such as a chemical-mechanical polishing (CMP) process, are performed to planarize interconnect layers including metal structures and dielectric materials. Metal density variations in different regions of an interconnect layer can cause nonuniform polishing rates, resulting in an uneven surface across the interconnect layer and affecting subsequently-fabricated structures above the interconnect layer.

### BRIEF DESCRIPTION OF THE DRAWINGS

Aspects of the present disclosure are best understood from the following detailed description when read with the accompanying figures.

FIGS. 1A-1E are cross-sectional views of semiconductor structures including an interconnect layer, in accordance with some embodiments.

FIG. 2 is a flowchart of a method for analyzing an interconnect layer to determine different regions of the interconnect layer having different metal densities, in accordance with some embodiments.

FIGS. 3 and 4 are cross-sectional views of a structure including an interconnect layer, in accordance with some embodiments.

FIG. 5 is a flowchart of a fabrication method for the formation an interconnect layer, in accordance with some embodiments.

FIGS. 6 through 12 are cross-sectional views of intermediate structures during the fabrication of an interconnect layer, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

Semiconductor manufacturing processes can include operations to planarize a surface of a structure for subsequent fabrication. For example, a process of forming an interconnect layer on a substrate can include forming openings in a layer of dielectric material on the substrate, followed by blanket depositing a layer of metallic material (e.g., copper) in the openings. Further, a planarization process, such as a chemical-mechanical polishing (CMP) process, can be performed to remove the excessive metallic material outside the openings and planarize a top surface of the interconnect layer, which includes metal surfaces of the metallic material and non-metal surfaces of the dielectric material.

A CMP process involves applying an abrasive and/or corrosive chemical solution (also referred to as a slurry) on a polishing pad, against which the surface to be planarized is pressed. The planarization can be facilitated by the chemical reaction between the slurry and the surface, in combination with a relative mechanical motion between the surface and the polishing pad. However, due to their different chemical and mechanical properties, different parts of the surface with different materials can have different polishing rates. In particular, metal surfaces and non-metal surfaces can have different polishing rates. As a result, an overall polishing rate of a region of the surface can depend on a ratio of metal surface area to non-metal surface area in that region. Regions of the surface with greater polishing rates can experience more loss of material and over-polished, compared to surrounding regions with lower polishing rates and being under-polished. The consequence is unevenness of the surface after the CMP process, which is sometimes referred to as “dishing.” For example, a first region of the surface with a lower ratio of metal surface area to non-metal surface area can be polished more efficiently, compared to a second region of the surface with a higher ratio of metal surface area to non-metal surface area, or vice versa. In another example, different dielectric regions (e.g., oxide region vs. nitride region) of the surface can also experience different polishing rates. The unevenness of the surface after the CMP process can adversely affect a quality of structures fabricated on the surface in subsequent processes.

The embodiments described herein are directed to overcoming the challenges mentioned above. In some embodiments, an interconnect layer on a substrate can include a first region with a first metal density and a second region with a second metal density different from the first metal density. The first and second regions can further include first and second dielectric materials, respectively. The first and the second dielectric materials can be different and be chosen according to their different polishing rates to compensate for the polishing difference in the first and second regions due to their different metal densities, such that dishing can be mitigated (or even prevented).

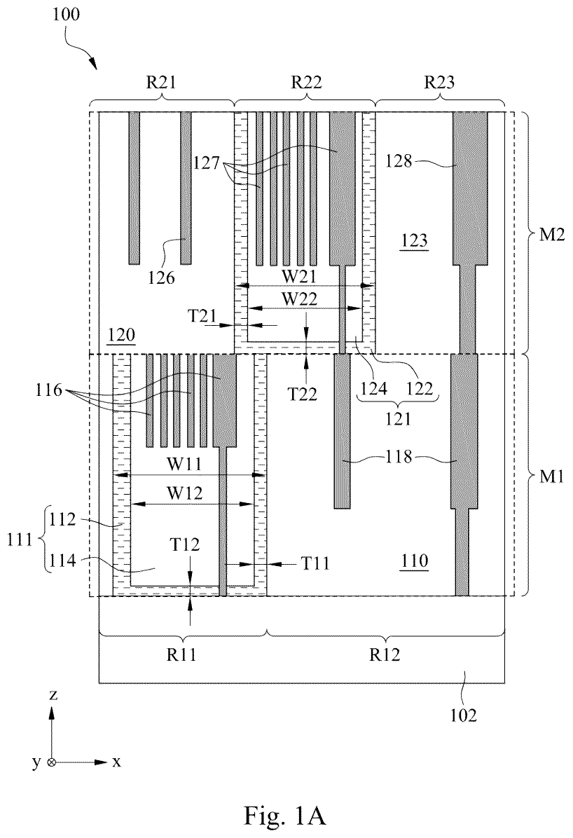

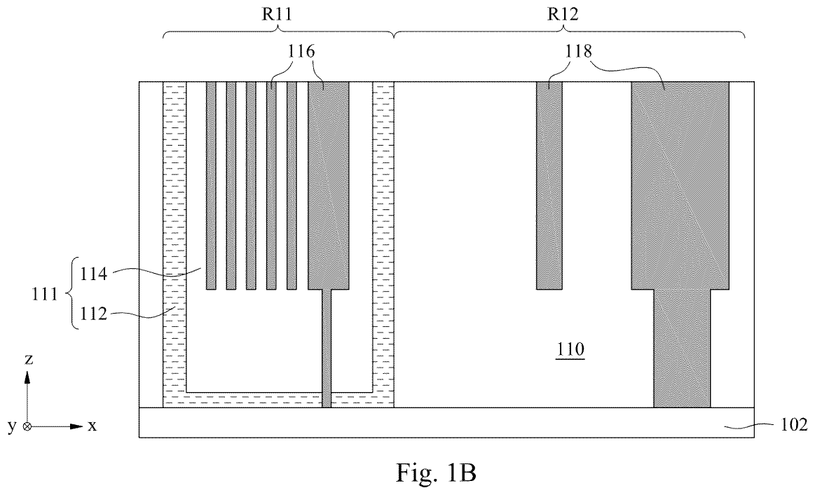

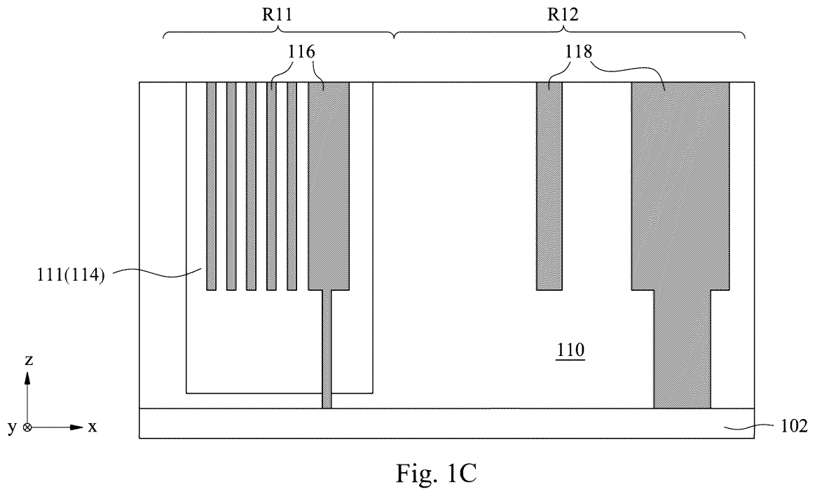

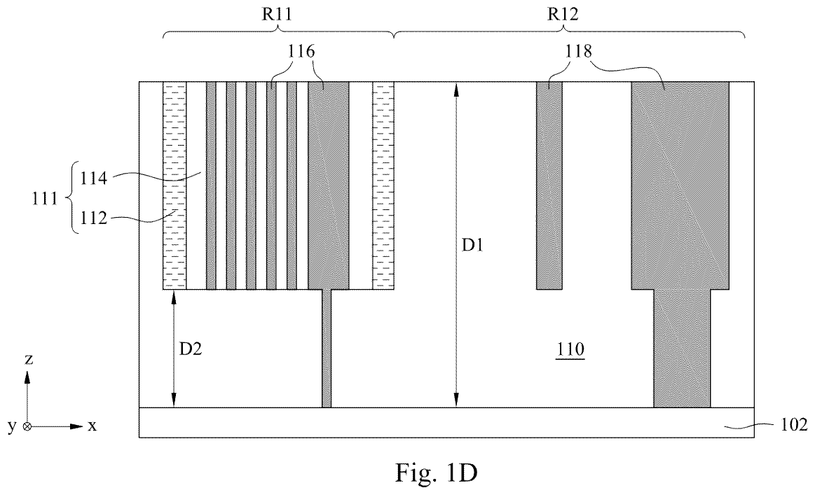

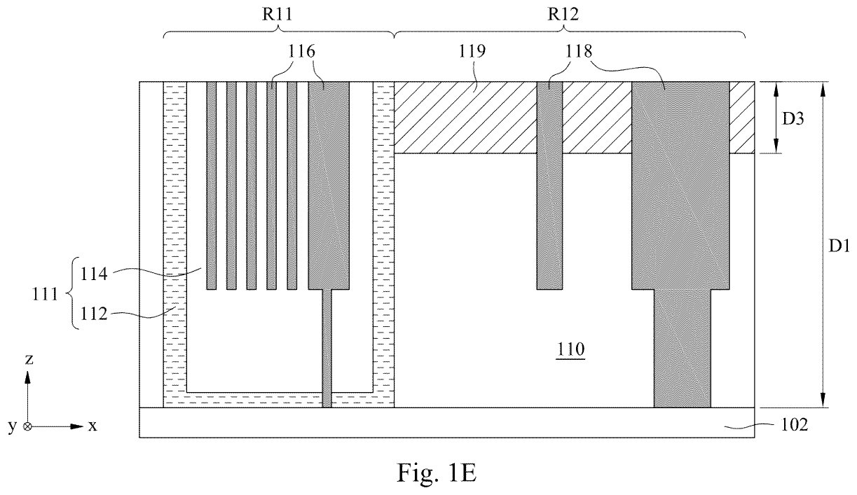

A semiconductor structure 100 having multiple interconnect layers M1 and M2 formed over a substrate 102 is described with reference to FIG. 1A, according to some embodiments. FIG. 1A illustrates a cross-sectional view of semiconductor structure 100, according to some embodiments. Semiconductor structure 100 can be included in a microprocessor, memory cell, or other integrated circuit (IC).

Referring to FIG. 1A, substrate 102 can be a semiconductor material, such as silicon. In some embodiments, substrate 102 can include a crystalline silicon substrate (e.g., wafer). In some embodiments, substrate 102 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. In some embodiments, substrate 102 can be doped depending on design requirements (e.g., p-type substrate or n-type substrate). In some embodiments, substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 102 can be (100), (110), or (111). In some embodiments, substrate 102 can include semiconductor structures. For example, substrate 102 can include one or more layers of semiconductor devices and one or more interconnect layers. In some embodiments, substrate 102 can include one or more layers of semiconductor devices, such as metal oxide semiconductor field effect transistors (MOSFETs), including planar MOSFETs, fin field effect transistors (finFETs), gate-all-around field effect transistors (GAA FETs), complementary field effect transistors (CFETs), and/or vertical field effect transistors (VFETs). In some embodiments, substrate 102 can further include one or more interconnect layers with interconnect structures connecting the semiconductor devices among the one or more layers of semiconductor devices. In some embodiments, the interconnect layers in substrate 102 can be the same as or similar to interconnect layers M1 and M2.

Interconnect layer M1 can include multiple regions, such as regions R11 and R12. Each region can include one or more dielectric layers and an interconnect structure in the dielectric layers. For example, region R11 can include a dielectric layer 111 and an interconnect structure 116. Dielectric layer 111 can further include one or more dielectric sublayers, such as sublayers 112 and 114. Similarly, region R12 can include a dielectric layer 110 and an interconnect structure 118. Although FIG. 1A shows that dielectric layer 110 does not include multiple sublayers and that dielectric layer 111 includes two sublayers 112 and 114, both dielectric layers 110 and 111 can include any number of sublayers. In some embodiments, top surfaces of regions R11 and R12 can be coplanar. In particular, top surfaces of dielectric layers 110 and 111, together with top surfaces of interconnect structures 116 and 118 can be coplanar. In some embodiments, interconnect layer M1 can have a thickness between about 20 nm and about 300 nm. This thickness range is not limiting and thicker or thinner interconnect layers outside the provided range are possible.

Each of dielectric layers 110 and 111 can include one or more dielectric materials, such as silicon oxide (SiO₂), silicon oxycarbide (SiOxC), silicon oxynitride (SiON), silicon nitride (SiN), silicon carbon nitride (SiCN), silicon carbide (SiC), silicon oxycarbon nitride (SiOCN), silicon germanium oxide (SiGeOₓ), or a combination thereof. Dielectric layers 110 and 111 can include different dielectric materials having different properties, such as different dielectric constants, different carbon concentrations, different porosities, different breakdown voltages, and different hardnesses. In some embodiments, dielectric constants of dielectric layers 110 and 111 can be between about 1 and about 3.9. For example, dielectric constants of dielectric layers 110 and 111 can be between about 3.7 and about 3.9, between about 3.5 and about 3.7, between about 3.2 and about 3.5, between about 2.7 and about 3.2, and between about 2.4 and about 2.7. In some embodiments, carbon concentrations of dielectric layers 110 and 111 can be between about 0% and about 30%. For example, carbon concentrations of dielectric layers 110 and 111 can be between about 0% and about 5%, between about 5% and about 10%, between about 10% and about 15%, between about 15% and about 20%, between about 20% and about 25%, and between about 25% and about 30%. In some embodiments, porosities of dielectric layers 110 and 111 can be between about 0% and about 10%. For example, porosities of dielectric layers 110 and 111 can be between about 0% and about 2%, between about 2% and about 5%, between about 5% and about 8%, and between about 8% and about 10%. In some embodiments, average sizes of pores in dielectric layers 110 and 111 can be between about 3 Å and about 15 Å. For example, average sizes of pores in dielectric layers 110 and 111 can be between about 3 Å and about 5 Å, between about 5 Å and about 8 Å, between about 8 Å and about 12 Å, and between about 12 Å and about 15 Å. In some embodiments, breakdown voltages of dielectric layers 110 and 111 can be between about 5 MV/cm and about 10 MV/cm. For example, breakdown voltages of dielectric layers 110 and 111 can be between about 5 MV/cm and about 6 MV/cm, between about 6 MV/cm and about 8 MV/cm, and between about 8 MV/cm and about 10 MV/cm.

Each of interconnect structures 116 and 118 can be embedded in its host dielectric layer. For example, as shown in FIG. 1A, interconnect structures 116 is embedded in dielectric layer 111, and interconnect structures 118 is embedded in dielectric layer 110. In some embodiments, interconnect structures 116 and 118 can include interconnect lines extending along horizontal directions (e.g., along the y-axis) and provide electrical connections within interconnect layer M1. In some embodiments, interconnect structures 116 and 118 can include interconnect vias that extend through interconnect layer M1 (e.g., along the z-axis) and provide electrical connections for layers above and below interconnect layer M1.

Each of interconnect structures 116 and 118 can include one or more suitable metallic materials, such as copper (Cu), tungsten (W), titanium (Ti), silver (Ag), ruthenium (Ru), molybdenum (Mo), cobalt (Co), aluminum (Al), iridium (Ir), nickel (Ni), metal alloys, and a combination thereof. Therefore, interconnect structures 116 and 118 can also be referred to as metal structures 116 and 118. In some embodiments, interconnect structures 116 and 118 can include the same metallic material. For example, interconnect structures 116 and 118 can include Cu. In some embodiments, interconnect structures 116 and 118 can include different metallic materials. In some embodiments, each of interconnect structures 116 and 118 can include a seed layer disposed at its interface with the host dielectric layer. Such a seed layer can have a thickness of a few nanometers and can be formed by a physical vapor deposition (PVD) process, a chemical vapor deposition (CVD) process, or an atomic layer deposition (ALD) process. The seed layer can serve as an electrode for forming interconnect structures 116 and 118 in an electro-plating process.

In some embodiments, top surfaces of regions R11 and R12 in interconnect layer M1 can have different metal densities. Here, a metal density of a region refers to a percentage of metal surface area on a top surface of that region and quantifies how much of that top surface is metallic. For example, referring to FIG. 1A, a top surface of region R11 includes metal surfaces corresponding to top surfaces of interconnect structures 116 and non-metal surfaces corresponding to top surfaces of dielectric layer 111. Similarly, a top surface of region R12 includes metal surfaces corresponding to top surfaces of interconnect structures 118 and non-metal surfaces corresponding to top surfaces of dielectric layer 110. Denoting a metal surface area within a region by Am, and a non-metal surface area within that region by An, then a metal density can be expressed as Am/(Am+An). Another quantity to quantify how much of the surface is metallic is a ratio of the metal surface area to the non-metal surface area Am/An. As shown as an example in FIG. 1A, the metal density of region R11 is greater than the metal density of region R12.

In some embodiments, the dielectric materials of dielectric layers 110 and 111 can be selected to compensate for the difference in planarizing regions R11 and R12 in a CMP process due to their different metal densities, so that the overall polishing rates of regions R11 and R12 can be substantially matched and dishing can be mitigated (or even prevented). Selecting the dielectric materials of dielectric layers 110 and 111 can be based on factors and parameters in the CMP process, such as the type of slurry, the condition of the polishing pad, the speed of the relative motion between the surface to be planarized and the polishing pad, and the pressure applied on the substrate against the polishing pad.

In some embodiments, if a polishing rate of the metal surfaces is higher than a polishing rate of the non-metal surfaces in a CMP process, considering the higher metal density in region R11 compared to region R12, the dielectric materials of dielectric layers 110 and 111 can be selected, such that dielectric layer 110 of region R12 can have a higher polishing rate compared to that of dielectric layer 111 of region R11. For example, dielectric layer 110 can include a dielectric material with a higher porosity, a larger average size of pores, a higher carbon concentration, a lower dielectric constant, a lower hardness, and/or a lower breakdown voltage compared to dielectric materials included in dielectric layer 111. On the other hand, in some embodiments, if a polishing rate of the metal surfaces is lower than a polishing rate of the non-metal surfaces in a CMP process, considering the higher metal density in region R11 compared to region R12, the dielectric materials of dielectric layers 110 and 111 can be selected such that dielectric layer 110 of region R12 can have a lower polishing rate compared to that of dielectric layer 111 of region R11. For example, dielectric layer 110 can include a dielectric material with a lower porosity, a smaller average size of pores, a lower carbon concentration, a higher dielectric constant, a higher hardness, and/or a higher breakdown voltage compared to dielectric materials included in dielectric layer 111.

In some embodiments, a multilayer structure of dielectric layers 110 and/or 111 can provide options to tune their polishing rates to compensate for the different metal densities in regions R11 and R12. In some embodiments, as shown in FIG. 1A, different dielectric materials of sublayers 112 and 114 can be selected to adjust the polishing rate of dielectric layer 111. For example, sublayers 112 and 114 can have different porosities, different average sizes of pores, different carbon concentrations, different dielectric constants, and/or different breakdown voltages. Since both sublayers 112 and 114 are dielectrics, sublayers 112 and 114 can also be referred to as dielectric layers 112 and 114. In some embodiments, as shown in FIG. 1A, geometrical factors of sublayers 112 and 114 can also affect the polishing rate of dielectric layer 111. For example, dielectric layer 111 can have a total width W11, sublayer 114 can have a width W12, sublayer 112 can have a vertical portion with a thickness T11 and a bottom portion with a thickness T12. In some embodiments, sublayers 112 can be selected to enhance an adhesion of dielectric layer 111 on substrate 102 and side surfaces of 110.

Interconnect layer M2 can be disposed on interconnect layer M1 and can include multiple regions, such as regions R21, R22, and R23, each including a dielectric layer and an interconnect structure. For example, as shown in FIG. 1A, region R21 includes a dielectric layer 120 and an interconnect structure 126, region R22 includes a dielectric layer 121 and an interconnect structure 127, and region R22 includes a dielectric layer 123 and an interconnect structure 128. The description of the dielectric layers and interconnect structures of regions R11 and R12 in interconnect layer M1 applies to those of regions R21, R22, and R23, unless otherwise mentioned. In some embodiments, regions between different interconnect layers can have substantially the same metal density and the same dielectric layer. For example, regions R11 and R22 can have substantially the same metal density, sublayers 112 and 122 can include the same dielectric material, and sublayers 114 and 124 can include the same dielectric material. Similarly, regions R12 and R21 can have substantially the same metal density, and dielectric layers 110 and 120 can include the same dielectric material. In some embodiments, between different interconnect layers, regions with different metal densities can overlap in a vertical direction (e.g., along the z-axis). For example, as shown in FIG. 1A, region R22 of interconnect layer M2 can overlap with regions R11 and R12 of interconnect layer M1. In some embodiments, an interconnect structure of a region in an interconnect layer can electrically couple to interconnect structures of different regions in another interconnect layer. For example, as shown in FIG. 1A, interconnect structure 118 includes metal lines/vias connected with metal line/vias in interconnect structures 127 and 128.

In some embodiments, regions R21, R22, and R23 can have different metal densities. For example, as shown in FIG. 1A, the metal density of region R22 is greater than the metal densities of R21 and R23. In some embodiments, dielectric layers 120, 121, and 122 can include different dielectric materials to compensate for the different metal densities of regions R21, R22, and R23, so that overall polishing rates of regions R21, R22, and R23 can be substantially matched and dishing can be mitigated (or even prevented) when planarizing interconnect layer M2 in a CMP process. The selection of the dielectric materials for dielectric layers 120, 121, and 122 according to the metal densities of regions R21, R22, and R23 can follow the same scheme described above for selecting the dielectric materials for dielectric layers 110 and 111 according to the metal densities of regions R11 and R12, and is not repeated for simplicity.

In some embodiments, each of dielectric layers 120, 121, and 122 can include a multilayer structure. For example, as shown in FIG. 1A, dielectric layers 121 can include sublayers 122 and 124. The discussion of different dielectric materials and different geometric factors of sublayers 112 and 114 applies to sublayers 122 and 124, unless mentioned otherwise.

FIG. 1B illustrates a cross-sectional view of interconnect layer M1 as shown in FIG. 1A, according to some embodiments. FIGS. 1C-1E illustrate cross-sectional views of variations of interconnect layer M1 as shown in FIG. 1A, according to some embodiments. The description of the dielectric layers and interconnect structures of regions R11 and R12 in interconnect layer M1 in FIG. 1A applies to those in FIGS. 1B-1E, unless otherwise mentioned.

Referring to FIG. 1C, in some embodiments, dielectric layer 111 of region R11 can include sublayer 114 without sublayer 112, in comparison with the embodiments in FIGS. 1A and 1B.

Referring to FIG. 1D, in some embodiments, dielectric layer 111 of region R11 can have a thickness less than a thickness D1 of interconnect layer M1, in comparison with the embodiments in FIGS. 1A and 1B. For example, as shown in FIG. 1D, region R12 can include a first portion of dielectric layer 110 having thickness D1, region R11 can include a second portion of dielectric layer 110 having a thickness D2 less than thickness D1, and dielectric layer 111 can be disposed on the second portion of dielectric layer 110. In some embodiments, thickness D2 can be determined based on factors and parameters in the CMP process. In some embodiments, thickness D2 can be determined to optimize a mechanical strength of dielectric layer 111. In some embodiments, a ratio of thickness D2 to thickness D1 can be between about 0.1 and about 0.9. In some embodiments, bottom surfaces of sublayers 112 and 114 can be in contact with a top surface of the portion of dielectric layer 110, and thicknesses of sublayers 112 and 114 can be substantially the same. In some embodiments, the thicknesses of sublayers 112 and 114 can be substantially the same as the thickness of one or more metal lines of interconnect structure 116.

Referring to FIG. 1E, in some embodiments, region R12 can further include a dielectric layer 119 disposed on dielectric layer 110 and embedding upper portions of interconnect structure 118, in comparison with the embodiments in FIGS. 1A and 1B. In some embodiments, dielectric layer 119 can include dielectric materials different from dielectric layers 110 and/or 111. In some embodiments, a ratio of thickness D3 of dielectric layer 119 to thickness D1 can be between about 0.1 and about 0.9. Similar to the consideration of selecting the dielectric materials of dielectric layers 110 and 111, material and geometrical factors of dielectric layer 119 can be determined based on factors and parameters in the CMP process. In some embodiments, a hardness of dielectric layer 119 can be different from those of dielectric layers 110 and 111. For example, dielectric layer 119 can be harder than dielectric layer 110 to reduce dishing of region R12.

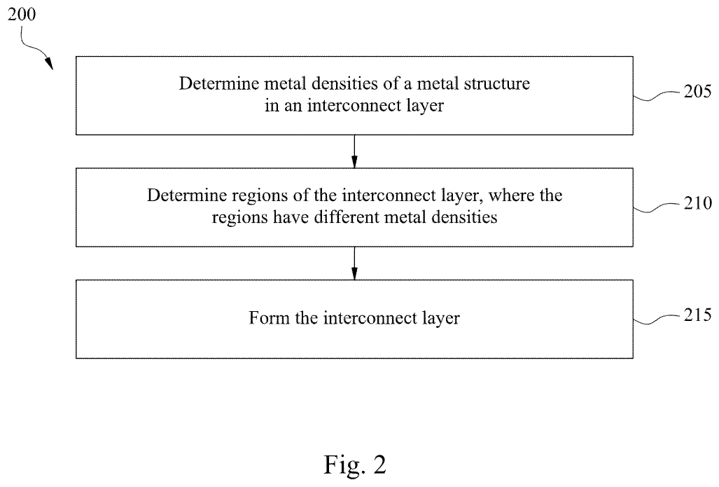

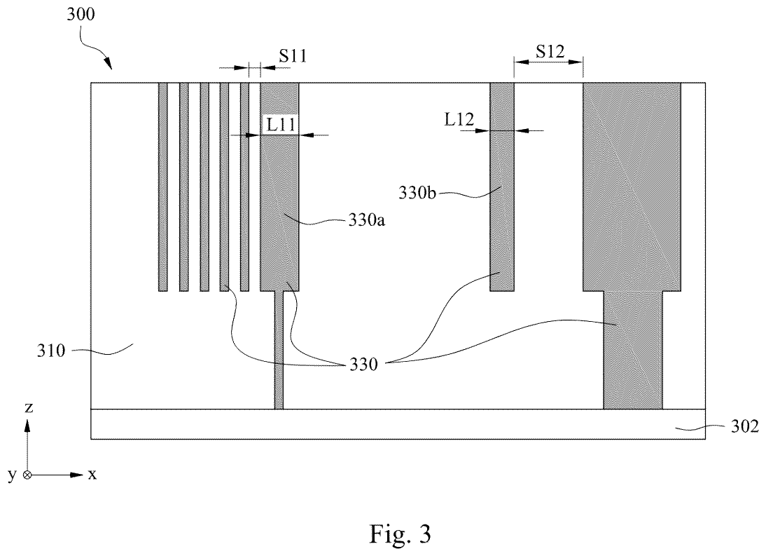

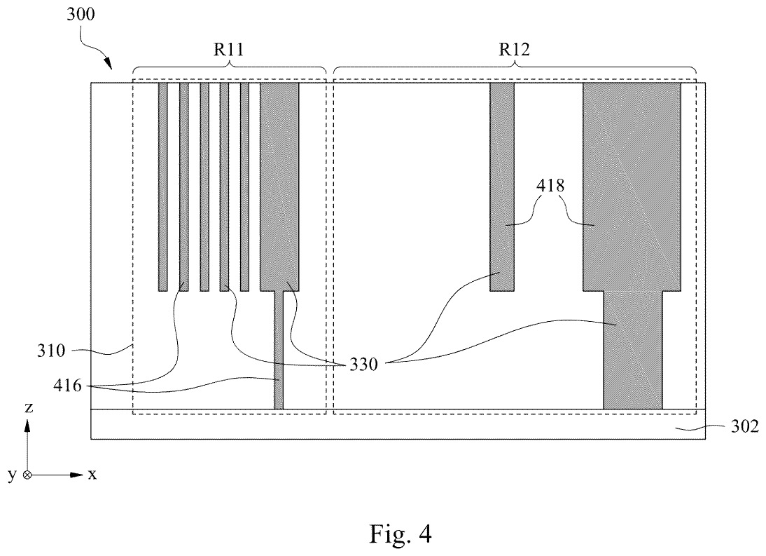

FIG. 2 is a flowchart of a method 200 for determining different regions of the interconnect layer having different metal densities, in accordance with some embodiments. For illustrative purposes, the operations illustrated in FIG. 2 will be described with reference to FIGS. 3 and 4, which are cross-sectional views of a structure including the interconnect layer, in accordance with some embodiments. Operations of method 200 can be performed in a different order or not performed depending on specific applications. Accordingly, it is understood that additional processes can be provided before, during, and after method 200, and that some other processes may only be briefly described herein.

In operation 205, metal densities of a metal structure in the interconnect layer can be determined. For example, as described with reference to FIG. 3, a structure 300 can include an interconnect layer 310 on a substrate 302. Interconnect layer 310 can include a metal structure 330. Metal structure 330 can include a number of interconnect structures the same as or similar to interconnect structures 116, 118, 126, 127, and 128 as shown in FIG. 1A. FIG. 3 shows that (i) a metal line 330a having a width L11 and a spacing S11 between metal line 330a and a metal line adjacent to the metal line 330a, and (ii) a metal line 330b having a width L12 and a spacing S12 between metal line 330b and a metal line adjacent to metal line 330b. Width to space ratios L11/S11 and L12/S12 can be used to determine metal densities of different portions of metal structure 330.

For example, as shown in FIG. 3, since width L11 is greater than width L12 and spacing S11 is less than spacing S12, width to space ratio L11/S11 is greater than width to space ratio L12/S12, indicating that a metal density around metal line 330a is greater than a metal density around metal line 330b. In some embodiments, a number of metal lines in a portion of metal structure 330 can be sampled, and the metal density of the portion of metal structure 330 can be determined by averaging width to space ratios of each of the sampled metal lines. In some embodiments, the metal density of metal structure 330 can be determined as a function of coordinates on the top surface of interconnect layer 310 to quantify how the metal density changes in different portions of metal structure 330.

Referring to FIG. 2, in operation 210, regions of the interconnect layer can be determined according to the metal densities of portions of the metal structure in the regions. Here, a metal density of portions of the metal structure in a region is also referred to as the metal density of the region. For example, as described with reference to FIG. 4, regions R11 and R12 can be determined in interconnect layer 310, with the metal density of region R11 greater than the metal density of region R12. Once the regions with different metal densities are determined, the metal structure can be separated into interconnect structures in different regions. For example, as described with reference to FIG. 4, metal structure 330 is separated into metal structures 416 and 418 included in regions R11 and R12, respectively. Metal structures 416 and 418 can correspond to interconnect structures 116 and 118, respectively, as shown in FIG. 1A.

In some embodiments, determining regions of the interconnect layer can include comparing metal densities of different portions of metal structure 330 with a reference value. For example, if an average width to space ratio of a portion of metal structure 330 is greater than the reference value, the portion belongs to region R11. Similarly, if the average width to space ratio of the portion of metal structure 330 is less than the reference value, the portion belongs to region R12. In some embodiments, the average width to space ratio of the portion in region R11 or R12 is substantially equal to a ratio of a metal surface area to a non-metal surface area in region R11 or R12, respectively. In some embodiments, the reference value can be between about 1.0 and about 3.0. For example, the reference value can be between about 1.0 and about 1.4, between about 1.4 and about 2.0, between about 2.0 and about 2.5, and between about 2.5 and about 3.0. In some embodiments, the reference value can be about 1.0, about 1.14, about 1.2, about 1.5, about 2.0, about 2.5, and about 3.0. In some embodiments, determining regions of the interconnect layer can include comparing metal densities of different portions of metal structure 330 with a number of reference values v₁, v₂, . . . . vₙ₋₁, vₙ, with 0<v₁<v₂<. . . <vₙ₋₁<vₙ, forming regimes [0, v₁], [v₁, v₂], . . . [vₙ₋₁, vₙ]. The portions of metal structure 330 with metal densities within the same regime can be determined to belong to the same region.

Determining the regions of the interconnect layer can further include determining the dielectric materials to be used to form the regions of the interconnect layer in subsequent processes, according to the metal densities of the regions. For example, as described with reference to FIG. 4, since the metal density of region R11 is greater than the metal density of region R12, a first dielectric material used to form region R11 can be selected to be different from a second dielectric material used to form region R12. For example, the first dielectric material can be selected to have a higher polishing rate compared to the second dielectric material, if the polishing rates of both the first and second dielectric materials are higher than a polishing rate of metal structure 330. On the other hand, the first dielectric material can be selected to have a lower polishing rate compared to the second dielectric material, if the polishing rates of both the first and second dielectric materials are lower than a polishing rate of metal structure 330. With the proper selection of the dielectric materials for regions R11 and R12 by considering the polishing rates of the dielectric materials and the different metal densities of regions R11 and R12, the overall polishing rates of regions R11 and R12 can be substantially matched to mitigate (or prevent) dishing.

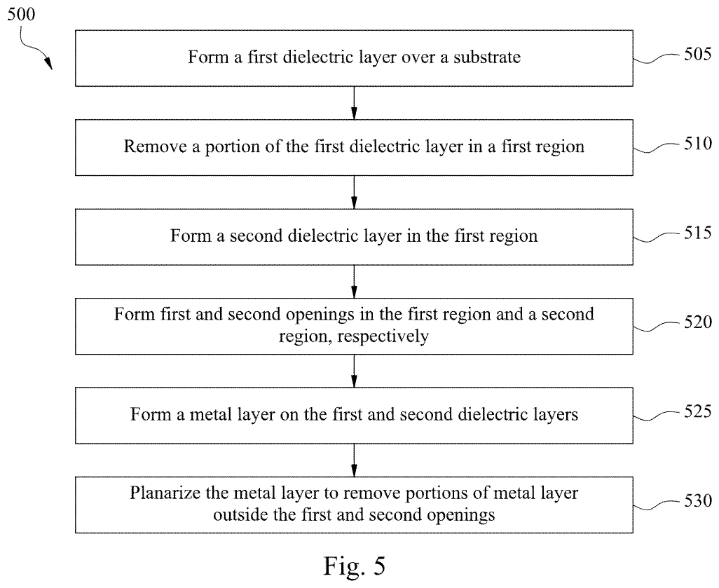

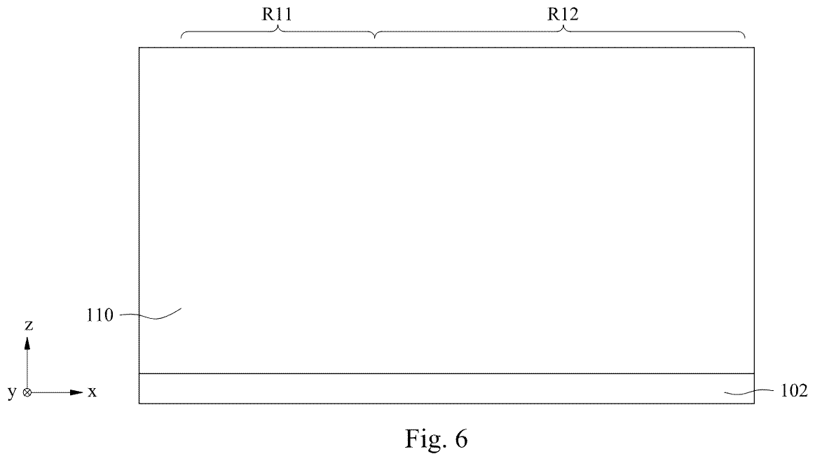

Referring to FIG. 2, method 200 proceed with operation 215 to form the interconnect layer. Operation 215 is detailed in FIG. 5, which is a flowchart of a method 500 for forming the interconnect layer, in accordance with some embodiments. For illustrative purposes, the operations illustrated in FIG. 5 will be described with reference to the example fabrication process as illustrated in FIGS. 6-12, which are cross-sectional views of intermediate structures during the fabrication of the interconnect layer, in accordance with some embodiments. Elements in FIGS. 6-12 with the same annotations as elements in FIG. 1A are described above. Operations of method 500 can be performed in a different order or not performed depending on specific applications. Accordingly, it is understood that additional processes can be provided before, during, and after method 500, and that some other processes may only be briefly described herein.

Referring to FIG. 5, in operation 505, a first dielectric layer is formed over a substrate. For example, as described with reference to FIG. 6, dielectric layer 110 is formed over substrate 102. In some embodiments, forming dielectric layer 110 can include blanket depositing a dielectric material on substrate 102 by a PVD process, a CVD process, a plasma enhanced CVD (PECVD) process, an ALD process, a sputtering process, or an electron-beam (e-beam) deposition process. In some embodiments, dielectric layer 110 can be formed in regions R11 and R12, which have been determined in operation 210. In some embodiments, the dielectric material can include the second dielectric material selected to form region R12 as discussed in the description of operation 210. In some embodiments, forming dielectric layer 110 can include doping dielectric layer 110 with carbon. In some embodiments, forming dielectric layer 110 can include increasing or decreasing a carbon concentration in dielectric layer 110. In some embodiments, forming dielectric layer 110 can include treating dielectric layer 110 to increase or decrease a dielectric constant of dielectric layer 110. In some embodiments, forming dielectric layer 110 can include treating dielectric layer 110 to increase or decrease a hardness of dielectric layer 110. For example, dielectric layer 110 can be treated in a thermal process, an ultraviolet (UV) process, a plasma process, an e-beam process, or a combination thereof, to adjust the carbon concentration, the dielectric constant, and/or the hardness of dielectric layer 110. In some embodiments, forming dielectric layer 110 can include introducing porogen in dielectric layer 110 using a porogen precursor in dielectric layer 110 to form pores in dielectric layer 110. For example, the porogen precursor can include propane (C3H8), benzene (C6H6), and/or alpha-terpinene (ATRP) (C10H16). In some embodiments, forming dielectric layer 110 can further include treating the porogen in dielectric layer 110 to increase or decrease a porosity of dielectric layer 110. For example, porogen in dielectric layer 110 can be treated in a thermal process, an UV process, a plasma process, an e-beam process, or a combination thereof, to adjust a density or sizes of pores in dielectric layer 110.

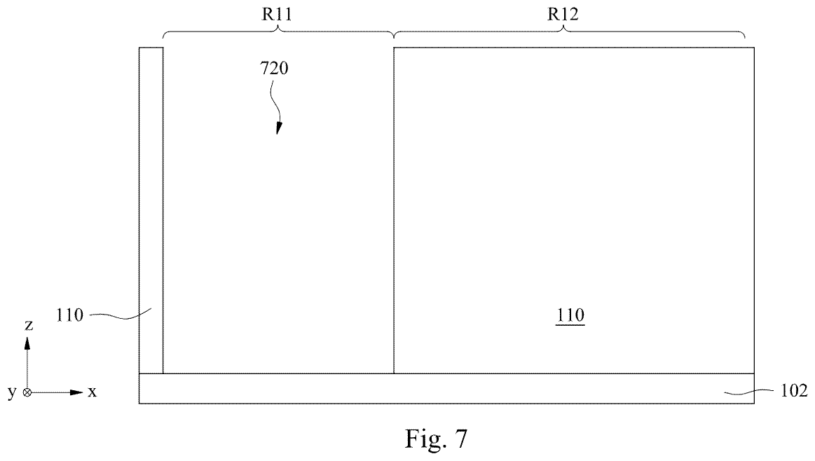

Referring to FIG. 5, in operation 510, a portion of the first dielectric layer in a first region is removed, where the first region is determined in operation 210 based on a metal density of the metal structure to be formed in the interconnect layer. For example, as described with reference to FIG. 7, a portion of dielectric layer 110 can be removed to form an opening 720 in region R11. Removing the portion of dielectric layer 110 can include a photolithography operation, including (i) spin-coating a photoresist over dielectric layer 110, (ii) patterning the photoresist to expose the portion of dielectric layer 110 in region R11, and (iii) etching the exposed portion of dielectric layer 110 to form opening 720. In some embodiments, after removing the portion of dielectric layer 110, side surfaces of dielectric layer 110 can be exposed. In some embodiments, after removing the portion of dielectric layer 110, a portion of substrate 102 can be exposed in opening 720.

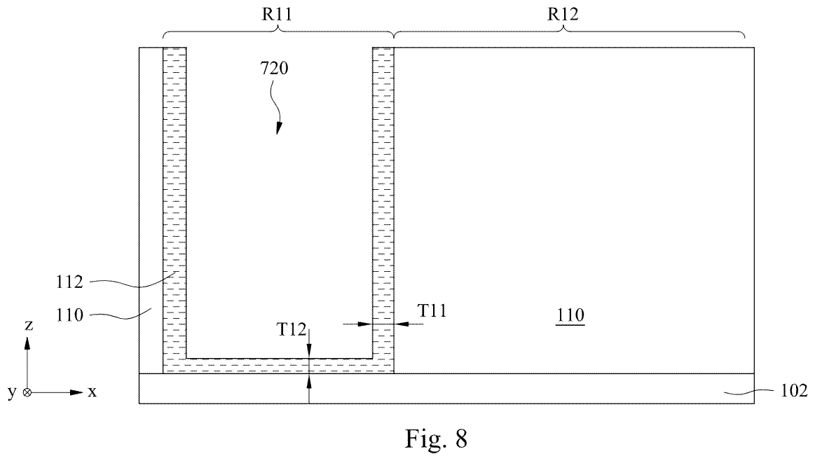

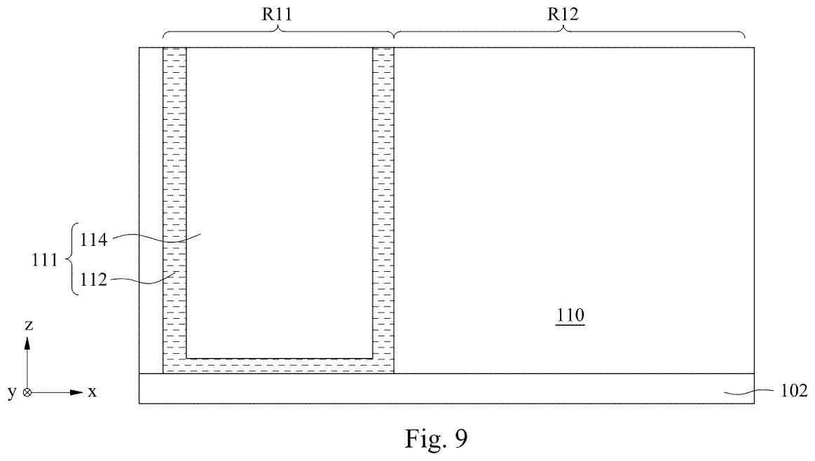

Referring to FIG. 5, in operation 515, a second dielectric layer is formed in the first region. For example, sublayer 112 can be formed on a bottom surface and side surfaces of opening 720, as described with reference to FIG. 8, and sublayer 114 can be formed on sublayer 112 to fill opening 720 and form dielectric layer 111, as described with reference to FIG. 9. In some embodiments, dielectric materials used to form dielectric layer 111 can be determined according to the metal density of region R11, as determined in operation 210. In some embodiments, the description of forming dielectric layer 110 in operation 505 applies to the formation of sublayers 112 and 114, unless mentioned otherwise.

In some embodiments, dielectric materials used to form sublayers 112 and 114 can be different from the dielectric material used to form dielectric layer 110, so that a polishing rate of dielectric layer 111 can be different from a polishing rate of dielectric layer 110. In some embodiments, dielectric materials used to form sublayers 112 and 114 can be the same as the dielectric material used to form dielectric layer 110, but sublayers 112 and 114 can be treated in a different manner than dielectric layer 110, so that the polishing rate of dielectric layer 111 can be different from the polishing rate of dielectric layer 110. In some embodiments, sublayers 112 and 114 can be doped with carbon concentrations different from that of dielectric layer 110. In some embodiments, sublayers 112 and 114 can include porogen precursors different from that in dielectric layer 110.

In some embodiments, sublayers 112 and 114 can be treated by different processes. In some embodiments, sublayers 112 and 114 can be treated by a thermal process with a temperature profile different from that for the treatment of dielectric layer 110. In some embodiments, sublayers 112 and 114 can be treated in a UV process with a UV intensity or a duration different from those for the treatment of dielectric layer 110. In some embodiments, sublayers 112 and 114 can be treated in a plasma process with a plasma power, a pressure, and/or a duration different from those for the treatment of dielectric layer 110. In some embodiments, sublayers 112 and 114 can be treated in an e-beam process with an e-beam power and/or a duration different from those for the treatment of dielectric layer 110.

In some embodiments, forming dielectric layer 111 can also include controlling parameters when depositing sublayers 112 and 114 to control the dimensions of sublayers 112 and 114. For example, a temperature, a pressure, a deposition time, and/or a combination thereof can be controlled to control thickness T12 of a bottom portion of sublayer 112 and/or thickness T11 of a vertical portion of sublayer 112, as described with reference to FIG. 8.

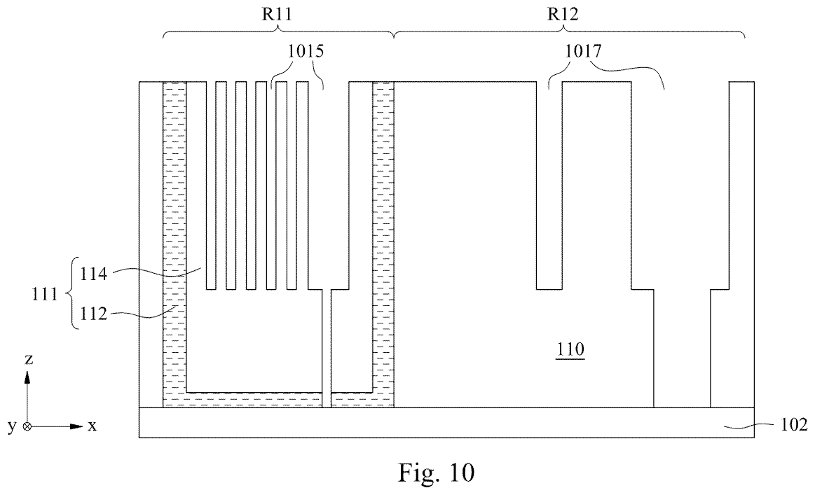

Referring to FIG. 5, in operation 520, first openings and second openings are formed in the first and second regions, respectively. For example, as described with reference to FIG. 10, first openings 1015 can be formed in region R11, and second openings 1017 can be formed in region R12. Forming openings 1015 ad 1017 can include a photolithography operation, which can include (i) spin-coating a photoresist over dielectric layers 110, 112, and 114, (ii) patterning the photoresist by a mask to expose portions of dielectric layers 110, 112, and 114, and (iii) etching the exposed portion of dielectric layer 110, 112, and 114. In some embodiments, a number of photolithography operations, each applying a different patterning mask, can be performed to achieve different depths of the openings, according to the requirement of forming the metal lines/vias in the interconnect structure.

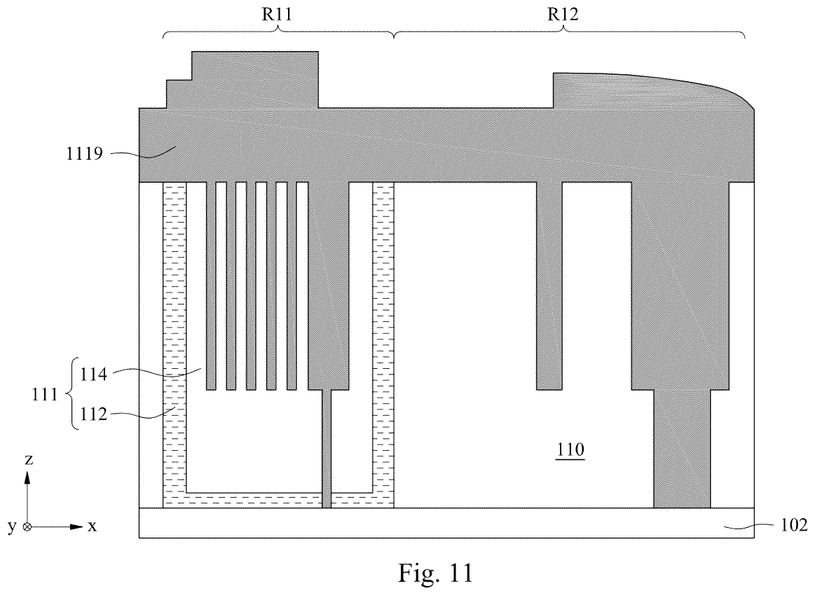

Referring to FIG. 5, in operation 525, a metal layer is formed on the first and second dielectric layers. For example, as described with reference to FIG. 11, a metal layer 1119 is formed on dielectric layers 110 and 111, filling openings 1015 and 1017. In some embodiments, forming metal layer 1119 can include (i) forming a seed layer by depositing a layer of conductive material on exposed surfaces of dielectric layers 110 and 111 using a CVD process, a PVD process, or an ALD process, and (ii) electroplating a metal material using the seed layer as an electrode to form metal layer 1119. In some embodiments, electroplating the metal material can include electroplating Cu and/or other metallic materials with low resistivity.

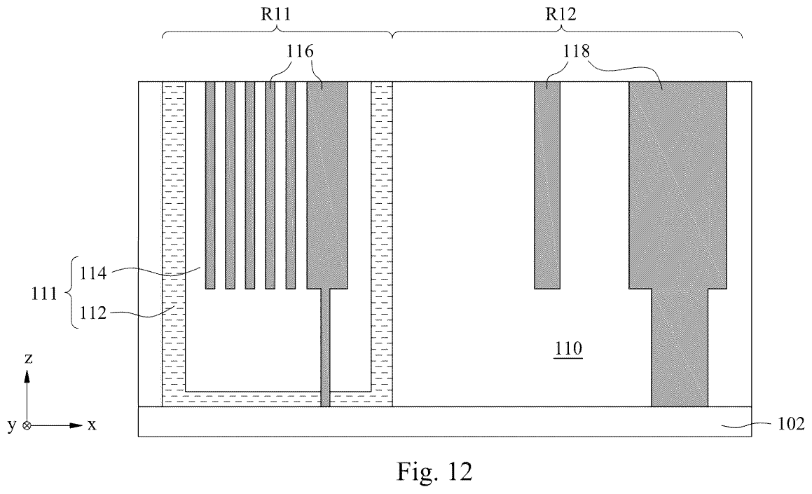

Referring to FIG. 5, in operation 530, portions of the metal layer outside the first and second openings can be removed by a planarization process. For example, as described with reference to FIG. 12, a CMP process can be performed to (i) remove portions of metal layer 1119 above dielectric layers 110 and 111 to form interconnect structures 116 and 118, and (ii) planarize top surfaces of dielectric layers 110 and 111 and interconnect structures 116 and 118. In some embodiments, a slurry can be applied in the CMP process. In some embodiments, parameters in the CMP process can be controlled so that the polishing rates of regions R11 and R12 can be matched. These parameters can include the type of slurry, the condition of the polishing pad, the speed of the relative motion between the substrate and the polishing pad, the pressure applied on the substrate against the polishing pad, and a combination thereof.

Although method 500 includes a process of forming only one interconnect layer, in some embodiments, after operation 530, the process can proceed for forming a second interconnect layer (e.g., interconnect layer M2 as shown in FIG. 1A), using the structure produced by operation 530 as a new substrate. For example, as described with reference to FIG. 1A, the process can continue by performing method 200 to analyze interconnect layer M2 and determine different regions R21, R22, and R23 according to their metal densities, and further by performing method 500 to form the interconnect layer M2 in a similar manner as forming interconnect layer M1. In some embodiments, other structures, such as one or more layers of semiconductor devices, can be formed on interconnect layer M1 after operation 530.

The embodiments described herein are directed to a structure of an interconnect layer and a method of forming the structure. In some embodiments, the interconnect layer can include first and second regions. In some embodiments, the first region can include a first dielectric layer and a first interconnect structure and the second region can include a second dielectric layer and a second interconnect structure. In some embodiments, the first region can have a first ratio of a metal surface area to a non-metal surface area in the first region and the second region can have a second ratio of a metal surface area to a non-metal surface area in the second region. In some embodiments, the first and second ratios can be different. In some embodiments, according to the first and second ratios the first and second dielectric layers can include dielectric materials selected and/or treated differently to match polishing rates of the first and second regions in a planarization process.

In some embodiments, a structure includes first and second dielectric regions on a substrate. The first dielectric region includes a first dielectric material and a first metal structure. The second dielectric region includes a second dielectric material and a second metal structure. The second dielectric material is different from the first dielectric material. Top surfaces of the first and second dielectric regions are coplanar. The first metal structure has a first density. The second metal structure has a second density different from the first density.

In some embodiments, a structure includes a substrate and an interconnect layer on the substrate. The interconnect layer includes first and second regions. The first region includes a first metal structure and a first dielectric material. The second region includes a second metal structure and a second dielectric material. A first ratio of a first metal surface area to a first non-metal surface area in the first region is less than a reference value. A second ratio of a second metal surface area to a second non-metal surface area in the second region is greater than the reference value.

In some embodiments, a method includes forming a first dielectric region on a substrate and including a first dielectric material, forming a second dielectric region on the substrate and including a second dielectric material different from the first dielectric material, and forming first and second metal structures in the first and second dielectric regions, respectively, with a first density of the first metal structure different from a second density of the second metal structure and where top surfaces of the first and second metal structures are coplanar.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
first and second dielectric regions on a substrate, wherein:
the first dielectric region comprises a first dielectric material;
the second dielectric region comprises a second dielectric material different from the first dielectric material; and
top surfaces of the first and second dielectric regions are coplanar;
a first metal structure in the first dielectric region and having a first density; and
a second metal structure in the second dielectric region and having a second density different from the first density.

2. The structure of claim 1, wherein:
the first density is less than the second density; and
a first porosity of the first dielectric material is less than a second porosity of the second dielectric material.

3. The structure of claim 1, wherein:
the first density is less than the second density; and
a first carbon concentration of the first dielectric material is less than a second carbon concentration of the second dielectric material.

4. The structure of claim 1, wherein:
the first density is less than the second density; and
a first dielectric constant of the first dielectric material is greater than a second dielectric constant of the second dielectric material.

5. The structure of claim 1, wherein:
the first density is less than the second density; and
a first breakdown voltage of the first dielectric material is greater than a second breakdown voltage of the second dielectric material.

6. The structure of claim 1, wherein top surfaces of the first and second metal structures are coplanar.

7. The structure of claim 1, wherein the first and second metal structures comprise copper.

8. A structure, comprising:
a substrate; and
an interconnect layer on the substrate and comprising first and second regions, wherein:
the first region comprises a first metal structure embedded in a first dielectric layer, wherein the first dielectric layer comprises a first dielectric material;
the second region comprises a second metal structure embedded in a second dielectric layer, wherein the second dielectric layer comprises a second dielectric material different from the first dielectric material, and wherein thicknesses of the first and second dielectric layers are different;
a first ratio of a first metal surface area to a first non-metal surface area in the first region is less than a reference value; and
a second ratio of a second metal surface area to a second non-metal surface area in the second region is greater than the reference value.

9. The structure of claim 8, wherein the reference value is between about 1.0 and about 1.4.

10. The structure of claim 8, wherein top surfaces of the first and second regions are coplanar.

11. The structure of claim 8, wherein the second region further comprises a third dielectric material layer on bottom and side surfaces of the second region, wherein the third dielectric material is different from the second dielectric material.

12. The structure of claim 8, wherein the second region further comprises a third dielectric layer on the second dielectric layer and embedding an upper portion of the second metal structure.

13. The structure of claim 8, further comprising an other interconnect layer on the interconnect layer and comprising third and fourth regions, wherein:
the third region comprises a third metal structure and the first dielectric material;
the fourth region comprises a fourth metal structure and the second dielectric material;
a third ratio of a third metal surface area to a third non-metal surface area in the third region is substantially equal to the first ratio; and
a fourth ratio of a fourth metal surface area to a fourth non-metal surface area in the fourth region is substantially equal to the second ratio.

14. The structure of claim 13, wherein the third region overlaps with the first and second regions.

15. A method, comprising:
forming, on a substrate, a first dielectric region comprising a first dielectric material;
forming, on the substrate, a second dielectric region comprising a second dielectric material different from the first dielectric material; and
forming first and second metal structures in the first and second dielectric regions, respectively, wherein a first density of the first metal structure is different from a second density of the second metal structure, and wherein top surfaces of the first and second metal structures are coplanar.

16. The method of claim 15, wherein forming the second dielectric region comprises:
removing a portion of the first dielectric material to form an opening; and
depositing the second dielectric material in the opening.

17. The method of claim 15, wherein forming the second dielectric region comprises increasing a porosity of the second dielectric region.

18. The method of claim 15, wherein forming the second dielectric region comprises decreasing a dielectric constant of the second dielectric region.

19. The method of claim 15, wherein forming the second dielectric region comprises:
removing a portion of the first dielectric material to expose a side surface of the first dielectric region;
forming a layer of a third dielectric material on the substrate and the side surface of the first dielectric region; and
depositing the second dielectric material on the layer of the third dielectric material.

20. The method of claim 15, wherein forming the first and second metal structures comprises:
forming openings in the first and second dielectric regions;
forming a metal layer in the openings; and
planarizing the metal layer, the first dielectric region, and the second dielectric region.
